(19) United States
(12) Patent Application Publication
(10) Pub. No.: US 2024/0334616 A1
(43) Pub. Date: Oct. 3, 2024

(54) HEAT SPREADER FOR MODIFIED EDGE COOLING

(71) Applicant: INTERNATIONAL BUSINESS MACHINES CORPORATION, ARMONK, NY (US)

(72) Inventors: Keiji Matsumoto, Yokohama-shi (JP); Mukta Ghate Farooq, HOPEWELL JCT, NY (US); John Knickerbocker, Monroe, NY (US)

(21) Appl. No.: 18/194,597

(22) Filed: Mar. 31, 2023

(51) Int. Cl. H05K 3/46; H05K 1/02; H05K 1/11; H05K 3/00; H05K 7/20

(52) U.S. Cl. CPC H05K 3/4602; H05K 1/0212; H05K 1/0218; H05K 1/024; H05K 1/115; H05K 3/0017; H05K 3/0055; H05K 7/20509; H05K 2201/09145

(57) ABSTRACT

A method for manufacturing an electronic package includes etching one or more lateral surfaces of a PCB laminate to expose power and ground planes of the PCB laminate. A protective coating is applied to the exposed power and ground planes. At least one heat-generating component is affixed to a top surface of the PCB laminate. A heat spreader having a base section and flanged edges is formed and attached to the heat-generating components and the PCB laminate lateral surfaces, where the flanged edges of the heat spreader are thermally connected to the PCB laminate lateral surfaces. During operation of the heat-generating components, the flanged edges dissipate heat from the PCB laminate lateral surfaces.

### BACKGROUND

### Technical Field

The present disclosure generally relates to the electronic, electrical, and computer arts, and more particularly, to heat spreaders for laminate cooling.

### Description of the Related Art

Heterogeneous Integration (HI) has widely been recognized to actualize high speed and high bandwidth communication between chips (such as a CPU, GPU, memory, etc.). Three-dimensional integration (3Di) is one prominent example of HI. However, it presents thermal challenges due to higher heat densities than conventional 2D packages. Specifically, a bottom chip of 3Di tends to be a high-heat dissipating chip due to the fact that it has many electrical interconnects with a substrate and is also highly functional (such as logic).

### SUMMARY

According to an embodiment of the present disclosure, an apparatus, or electronic package includes a printed circuit board (PCB) laminate having a core and embedded power planes and ground planes positioned adjacent the core. One or more heat-generating components are affixed to a top surface of the PCB laminate. A heat spreader is attached in thermal contact with at least one of the one or more heat-generating components and one or more lateral surfaces of the PCB laminate. The heat spreader includes flanged edges in thermal contact with the one or more PCB laminate lateral surfaces.

According to an embodiment of the present disclosure, a heat spreader includes a base section and a plurality of legs extending from the base section. Flanged edges extend from each of the plurality of legs in a direction different than that of the base section and the plurality of legs. The flanged edges define a thermal contact surface configured to receive at least one PCB laminate lateral surface for heat dissipation of at least one heat-generating component of an electronic package.

According to an embodiment of the present disclosure, a method for manufacturing an electronic package includes etching back one or more lateral surfaces of a PCB laminate, where the etching exposes power and ground planes of the PCB laminate. A protective coating is applied to the exposed power and ground planes. The electronic package is assembled. A heat spreader is formed having a base section, a plurality of legs extending from the base section, and flanged edges extending from the plurality of legs. The heat spreader is attached to at least one heat-generating component of the electronic package and the one or more PCB laminate lateral surfaces, where the flanged edges of the heat spreader are thermally connected to the one or more PCB laminate lateral surfaces. During operation of the at least one heat-generating component, the flanged edges dissipate heat from the one or more PCB laminate lateral surfaces.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 depicts a cross-sectional view of a conventional electronic package, consistent with an illustrative embodiment.

FIG. 2A presents a top view of a conventional printed circuit board laminate depicting a keep-out-zone, consistent with an illustrative embodiment.

FIG. 2B presents a magnified cross-sectional view of a conventional printed circuit board laminate depicting a keep-out-zone, consistent with an illustrative embodiment.

FIG. 3A depicts a top view of a substrate layer of a conventional uncut printed circuit board laminate sheet, consistent with an illustrative embodiment.

FIG. 3B presents a top view of a conventional uncut printed circuit board laminate sheet depicting a keep-out-zone, consistent with an illustrative embodiment.

FIG. 4 depicts a cross-sectional view of an apparatus embodying heat-generating components and a heat spreader, consistent with an illustrative embodiment.

FIG. 5A depicts a top view of a printed circuit board laminate with a keep-out-zone removed, consistent with an illustrative embodiment.

FIG. 5B depicts a magnified cross-sectional view of a printed circuit board laminate of FIG. 5A with the keep-out-zone removed, consistent with an illustrative embodiment.

FIG. 6 depicts a magnified cross-sectional view of a printed circuit board laminate with a protective coating covering ends of power and ground planes along a lateral surface of a printed circuit board laminate, consistent with an illustrative embodiment.

FIG. 7 depicts a magnified cross-sectional view of a heat spreader with a flanged edge and a thermal interface material contacting a lateral surface of a printed circuit board laminate, consistent with an illustrative embodiment.

FIG. 8A depicts a magnified cross-sectional view of a heat-generating electronic component affixed to a printed circuit board laminate embodying a plurality of thermal vias, consistent with an illustrative embodiment.

FIG. 8B depicts a magnified cross-sectional view of a heat spreader with flanged edges and a thermal interface material contacting a lateral surface of a printed circuit board laminate embodying a plurality of thermal vias, consistent with an illustrative embodiment.

FIG. 9 depicts a magnified cross-sectional view of a heat spreader contacting edges of a PCB laminate and embodying a protrusion extending into a thermal interface material, consistent with an illustrative embodiment.

FIG. 10 depicts a magnified cross-sectional view of a heat spreader contacting a lateral surface of a PCB laminate with a core embedded with power and ground planes, consistent with an illustrative embodiment.

FIG. 11A depicts an isometric view of an electronic package model, consistent with an illustrative embodiment.

FIG. 11B depicts a zoomed-in view of the electronic package model of FIG. 11A, consistent with an illustrative embodiment.

FIG. 12 presents a chart comparing distances between a chip edge and a printed circuit board laminate edge and manageable heat density, consistent with an illustrative embodiment.

FIG. 13A depicts, as an isometric view, an additional embodiment of an electronic package model, consistent with an illustrative embodiment.

FIG. 13B depicts a zoomed-in view of the additional embodiment of the electronic package model of FIG. 13A, consistent with an illustrative embodiment.

FIG. 14 presents a chart comparing thicknesses of power and ground planes in a core and manageable heat density, consistent with an illustrative embodiment.

FIG. 15A depicts a top view of a cross-sectional plane of a printed circuit board laminate of an electronic package model embodying a filled via, consistent with an illustrative embodiment.

FIG. 15B depicts an isometric view of a cross-sectional plane of a printed circuit board laminate of an electronic package model embodying a filled via, consistent with an illustrative embodiment.

FIG. 15C presents a chart comparing thermal conductivities of materials in a cross-sectional plane of a printed circuit board laminate of an electronic package model embodying a filled via, consistent with an illustrative embodiment.

FIG. 15D presents a chart providing thermal conductivity characteristics of a cross-sectional plane of a printed circuit board laminate of an electronic package model embodying a filled via, consistent with an illustrative embodiment.

FIG. 16A depicts a top view of a cross-sectional plane of an interconnection layer of an electronic package model, consistent with an illustrative embodiment.

FIG. 16B depicts an isometric view of a cross-sectional plane of an interconnection layer of an electronic package model, consistent with an illustrative embodiment.

FIG. 16C presents a chart comparing thermal conductivities of materials in a cross-sectional interconnection layer of an electronic package model, consistent with an illustrative embodiment.

FIG. 16D presents a chart providing thermal conductivity characteristics of a cross-sectional interconnection layer of an electronic package model, consistent with an illustrative embodiment.

FIG. 17 presents a chart providing thermal conductivity characteristics of an electronic package model, consistent with an illustrative embodiment.

FIG. 18 is a simple flowchart for a method for manufacturing an electronic package, consistent with an illustrative embodiment.

FIG. 19 is a simple flowchart for an additional method for manufacturing an electronic package, consistent with an illustrative embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

The term “semiconductor” as used herein denotes any semiconducting material including, for example, Si, Ge, SiGe, SiC, SiGeC, and III-V compound semiconductors such as InAs, GaAs and InP.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

As used herein, the terms “connected” and/or “thermally connected” are not meant to mean that the elements must be directly connected together-intervening elements may be provided between the “connected” or “thermally connected” elements. In contrast, if an element is referred to as being “directly connected” or “directly coupled” to another element, there are no intervening elements present.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

In conventional cooling from the top side of three-dimensional integrated circuits, generated heat is typically release at the top side of an electronic package. In 3Di, bottom chips are difficult to cool due to the fact that the heat must travel through the multiple layers in order to dissipate. This can lead to malfunction and, eventually, destruction of the chips.

In one aspect, the teachings herein are based on Applicants' insight that thermally contacting specific surfaces of laminates used in electronic packages optimizes cooling of electronic packages.

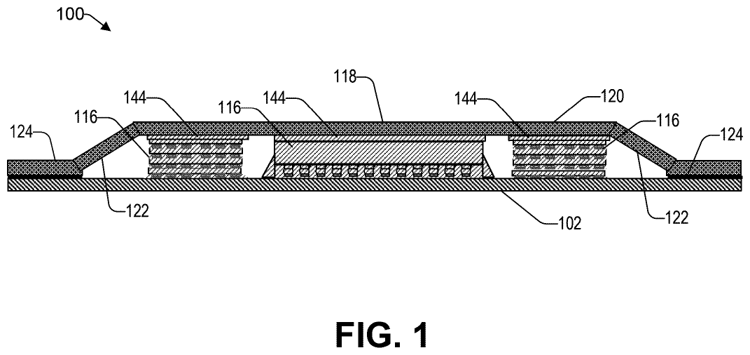

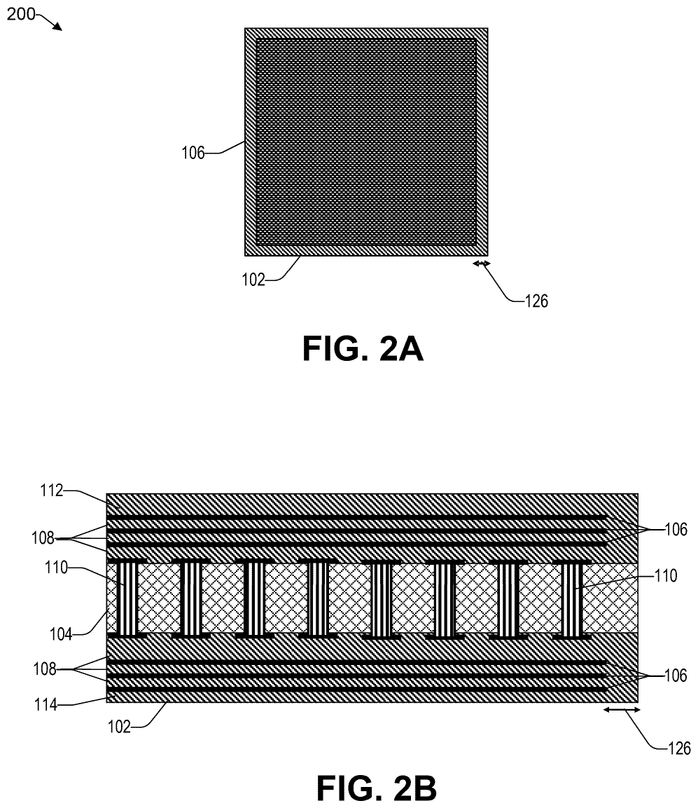

Reference is now made to FIG. 1, which depicts a cross-sectional view of a conventional electronic package 100, consistent with an illustrative embodiment. A PCB laminate 102 includes a laterally extending core 104 and embedded power planes and ground planes 106 positioned adjacent the core 104, as shown in FIG. 2B. The embedded power and ground planes 106 are separated by substrate 108, and together define the (PCB) laminate 102. Additionally shown in FIG. 2B, plated through holes 110 extend from an upper build-up layer 112 and through core 104 to a lower build-up layer 114. The plated through holes 110 create a thermally conductive path between upper build-up layer 112 and lower build-up layer 114 and may also provide heat for dissipation to core 104. One or more heat-generating components 116 are affixed to a top surface of PCB laminate 102. For exemplary purposes, heat-generating components 116 can include random-access or read-only memory, processors, or other computer circuitry.

As shown in FIG. 1, heat-generating components 116 include a semiconductor chip and a pair of three-dimensional integrated circuits positioned adjacent the semiconductor chip. A heat spreader 118 is thermally connected to the top sides of the heat-generating components 116 via base section 120. Thermal interface material (TIM) 144 is positioned between heat spreader 118 and the top sides of heat-generating components 116. Heat spreader 118 is further connected to PCB laminate 102 via a plurality of legs 122 extending from base section 120. A sealband 124 is positioned between ends of the plurality of legs 122 and PCB laminate 102 to provide protection to PCB laminate 102.

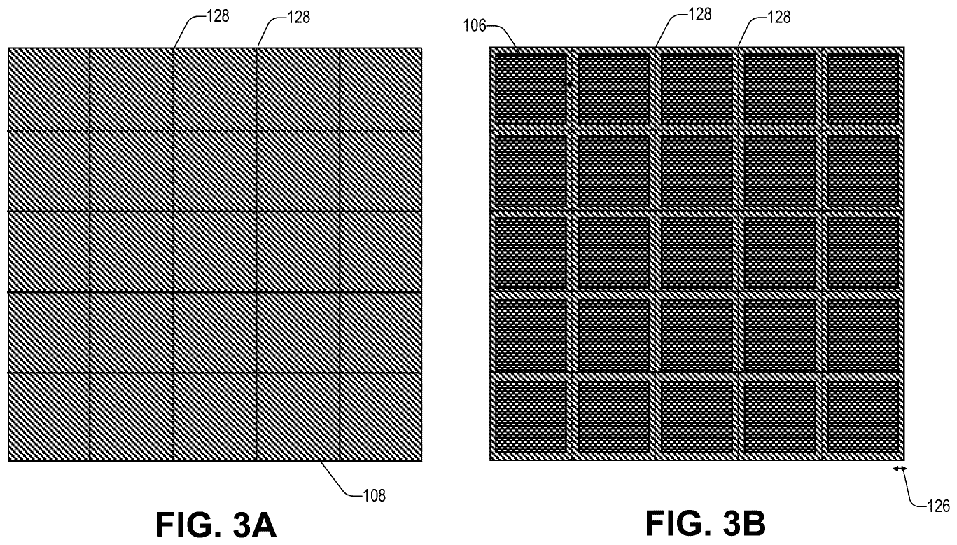

As shown in FIGS. 2A and 2B, a keep-out-zone 126 (denoted by a double-sided arrow) extends from the ends of power and ground planes 106. Keep-out-zone 126 refers to an area of the substrate 108 that are not overlapped by the power and ground planes 106 and that typically define an area of a PCB laminate where power and ground planes are absent and only include substrate material (around the perimeter of the power and ground planes 106). In a conventional fabrication process of a PCB laminate, cut lines 128 are formed in substrate 108 (FIG. 3A), which help define the keep-out-zone 126. As shown in FIG. 3B, the keep-out zone 126 is defined by the area between the edges of power and ground planes 106 and the exposed edges of a PCB laminate as well as between the edges of power and ground planes 106 and the non-exposed/adjacent edges of a PCB laminate, where the non-exposed adjacent edges of a PCB laminate are defined by cut lines 128.

In embodiments, substrate material is a dielectric material (may only be in keep-out-zone 126).

In conventional cooling of an electronic package, heat from heat-generating components are absorbed and dissipated by, for example, heat spreader 118 along the top side the electronic package. However, as the heat-generating components grow in height, the effectiveness of heat removal by heat spreader 118 is reduced. For example, a three-dimensional integrated circuit includes multiple heat-generating layers. Top layers of the three-dimensional integrated circuit may be effectively cooled by heat spreader 118, but heat from the bottom layers of the three-dimensional integrated circuit positioned adjacent PCB laminate 102 is not effectively dissipated.

Accordingly, the teachings herein provide methods and apparatuses for optimizing the cooling of electronic packages. The techniques described herein may be implemented in a number of ways. Example implementations are provided below with reference to the following figures.

### Example Electronic Package Structure

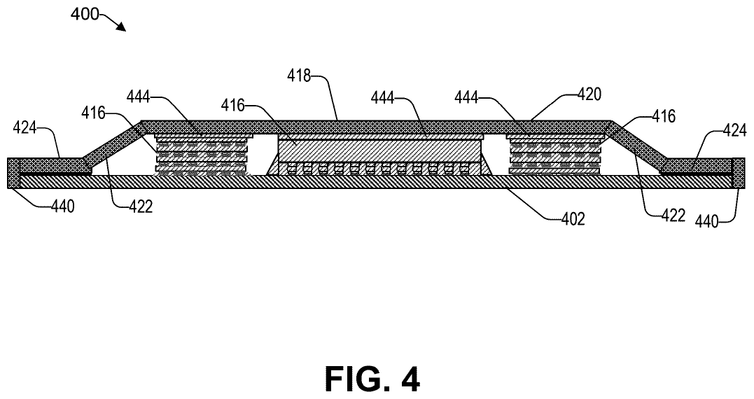

Reference is now made to FIG. 4, which depicts a cross-sectional view of an apparatus 400 embodying heat-generating components 416 and a heat spreader 418, consistent with an illustrative embodiment. As shown, apparatus 400 is an electronic package. One or more heat-generating components 416 are affixed to a top surface of a PCB laminate 402. For exemplary purposes and not by way of limitation, heat-generating components 416 include random-access or read-only memory, processors, or other computer circuitry. As shown in FIG. 4, heat-generating components 416 include a semiconductor chip and a pair of three-dimensional integrated circuits positioned adjacent the semiconductor chip. Heat spreader 418 is thermally connected to the top sides of the heat-generating components 416 via base section 420. Thermal interface material (TIM) 444 is positioned between heat spreader 418 and the top sides of heat-generating components 416. Heat spreader 418 is connected to PCB laminate 402 via a plurality of legs 422 extending from base section 420 A sealband (not depicted) is positioned between the plurality of legs 422 and PCB laminate 402 to provide protection to PCB laminate 402. Additionally, heat spreader 418 includes flanged edges 440 that extend from the plurality of legs 422 in a direction different than that of the base section 420 and the plurality of legs 422 of heat spreader 418. With reference to the PCB laminate 402, flanged edges 440 extend along lateral surfaces of PCB laminate 402 and further define a thermal contact surface configured to receive the lateral surfaces for heat dissipation of at least one of the heat-generating components 416. In this embodiment of apparatus 400, a keep-out-zone 426 is removed/absent from PCB laminate 402 so that ends of embedded power and ground planes 406 are exposed and thermally contact PCB laminate 402. This configuration provides additional heat dissipation from the heat-generating components 416 through the PCB laminate 402 to heat spreader 418.

In other embodiments, substrate material can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

### Example Processes for Electronic Package Structures

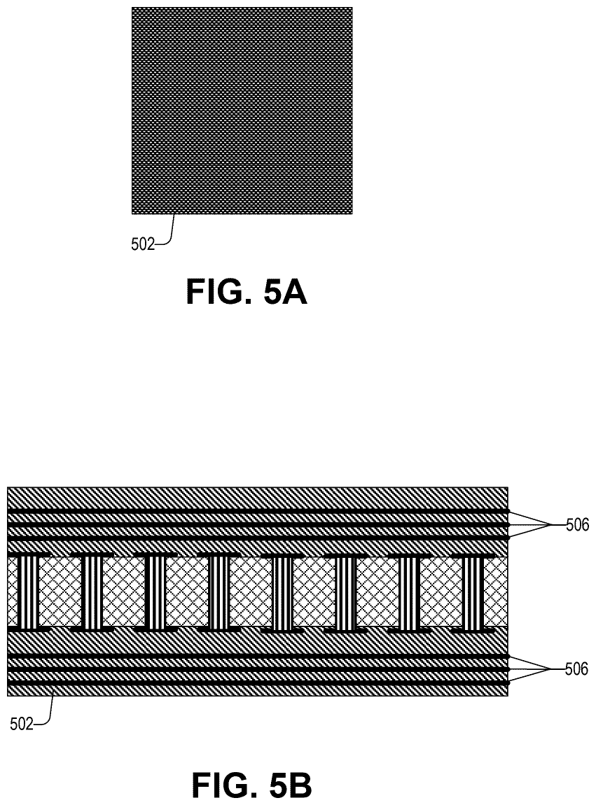

With the foregoing description of an example electronic package 400, it may be helpful to discuss an example process of manufacturing the same. To that end, FIGS. 5A to 7 illustrate various steps in the manufacture of an electronic package, consistent with illustrative embodiments. More specifically, FIG. 5A depicts a top view of a PCB laminate 502 with a keep-out-zone removed, consistent with an illustrative embodiment. In various embodiments, such as that shown in FIG. 5B, substrate material of a keep-out-zone is etched back/removed so that power and ground planes 506 are exposed (and cleaned) at the lateral surface of PCB laminate 502. For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Fabrication of the devices of FIGS. 5A to 7 can comprise multi-step sequences of, for example, photolithographic and/or chemical processing steps that facilitate gradual creation of electronic-based systems, devices, components, and/or circuits in a semiconducting and/or a superconducting device (e.g., an integrated circuit). For instance, the devices discussed herein can be fabricated on one or more substrates (e.g., a silicon (Si) substrates, and/or another substrate) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

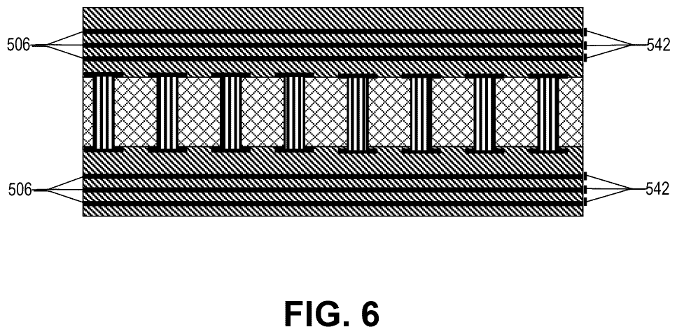

Reference is now made to FIG. 6, which depicts a magnified cross-sectional view of a PCB laminate 502 with a protective coating 542 applied to ends of power and ground planes 506 along a lateral surface of a PCB laminate 502, consistent with an illustrative embodiment. In one embodiment, the protective coating 542 is a corrosion-protective coating such as, but not limited to, benzotriazole (BTA). It is noted that a corrosion-protective coating is utilized for its negligible effects on thermal conduction. In relation to this embodiment, once corrosion-protective coating is applied to ends of power and ground planes 506, electronic package (for example, electronic package 400) is assembled. During assembly, the corrosion-protective coating is broken/removed and a second cleaning of the ends of the power and ground planes 506 is performed. In further embodiments, corrosion-protective coating is applied via reactive ion etching. Once the ends of the power and ground planes 506 are cleaned the second time, a second corrosion-protective coating is applied to the cleaned ends of the power and ground planes 506.

In another embodiment, protective coating 542 is a corrosion-resistant coating that is a metal. The metal may include, but is not limited to nickel/gold (Ni/Au) and titanium (Ti). It is noted that the metals disclosed are utilized for their negligible effects on thermal conduction. In further embodiments, corrosion-resistant coating is applied via any suitable techniques such as electroless plating and sputtering. In relation to this embodiment, once corrosion-resistant coating is applied to ends of power and ground planes 506, electronic package (for example, electronic package 400) is assembled. During assembly, the corrosion-protective coating is not broken/removed.

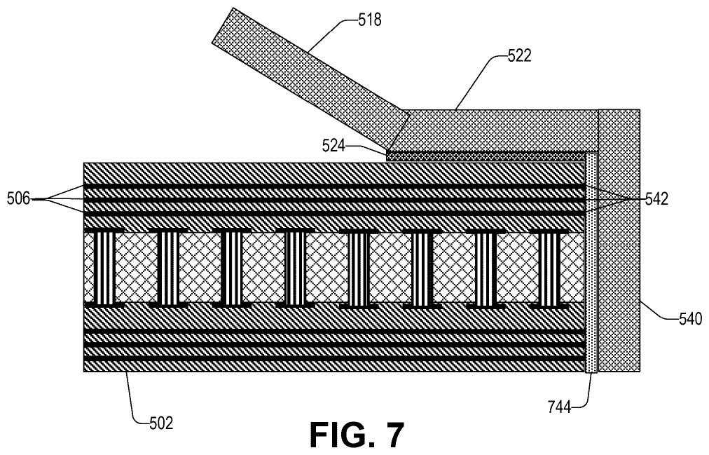

FIG. 7 depicts a magnified cross-sectional view of a heat spreader 518 with a flanged edge 540 and a thermal interface material (TIM) 744 contacting a lateral surface of a PCB laminate 502, consistent with an illustrative embodiment. As shown, heat spreader 518 is also connected to PCB laminate 502 via a leg 522 extending from base section (not depicted); a sealband 524 is positioned between leg 522 and PCB laminate 502 to provide protection to PCB laminate 102. Once protective coating 542 is applied to ends of power and ground planes 506 along a lateral surface of PCB laminate 502, the flanged edge 540 (having a thermal interface material 744 attached thereto) is thermally connected to a lateral surface of a PCB laminate 502 and electrical degradation of the power and ground planes 506 is prevented. In an embodiment, the thermal interface material 744 is a dielectric material.

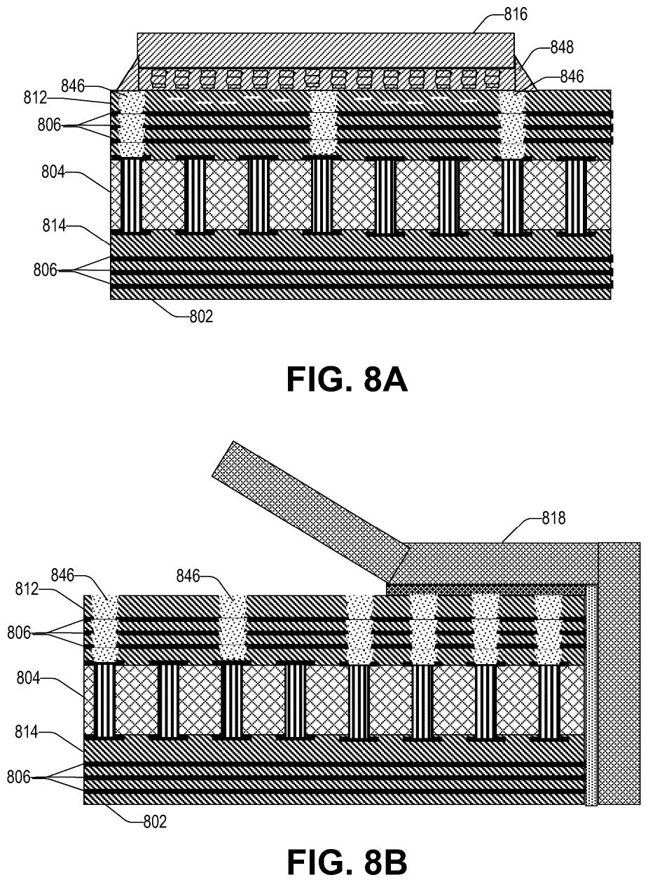

Reference is now made to FIG. 8A, which depicts a magnified cross-sectional view of a heat-generating component 816 affixed to a PCB laminate 802 embodying a plurality of thermal vias 846, consistent with an illustrative embodiment. As shown, heat-generating component 816 is a semiconductor chip positioned on an interconnection layer 848 affixed to PCB laminate 802. Thermal vias 846 positioned within an upper build-up layer 812 extend from interconnection layer 848 to core 804. The thermal vias 846 create a thermally conductive path between interconnection layer 848 and core 804. Thermal vias 846, as depicted, may also enable heat dissipation by providing heat to power and ground planes 806 embedded in upper build-up layer 812 and subsequently to heat spreader 818. As shown in FIG. 8B, thermal vias 846 may additionally be positioned toward an edge of the upper build-up layer 812 of PCB laminate 802 in order to provide additional thermal conduction. In further embodiments, thermal vias 846 may also or alternately be positioned within a lower build-up layer 814 in order to enable heat dissipation by providing heat to power and ground planes 806 embedded in lower build-up layer 814.

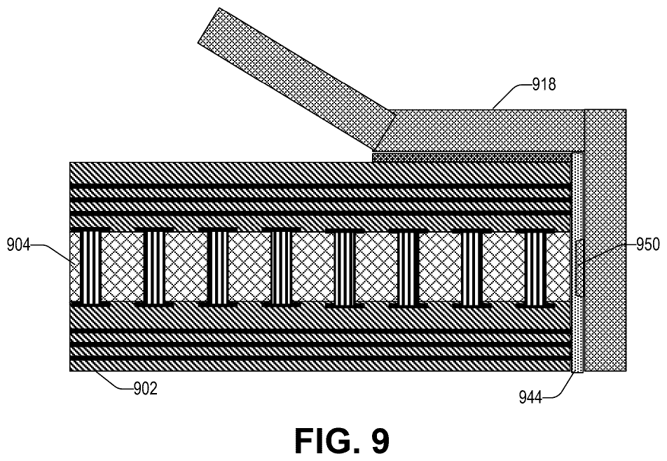

Reference is now made to FIG. 9, which depicts a magnified cross-sectional view of a heat spreader 918 contacting a lateral surface of a PCB laminate 902 and embodying a protrusion 950 extending into a thermal interface material 944, consistent with an illustrative embodiment. As shown, protrusion 950 extends into thermal interface material 944 adjacent core 904. Protrusion 944 minimizes the thickness of thermal interface material 944 to optimize heat dissipation out of core 904.

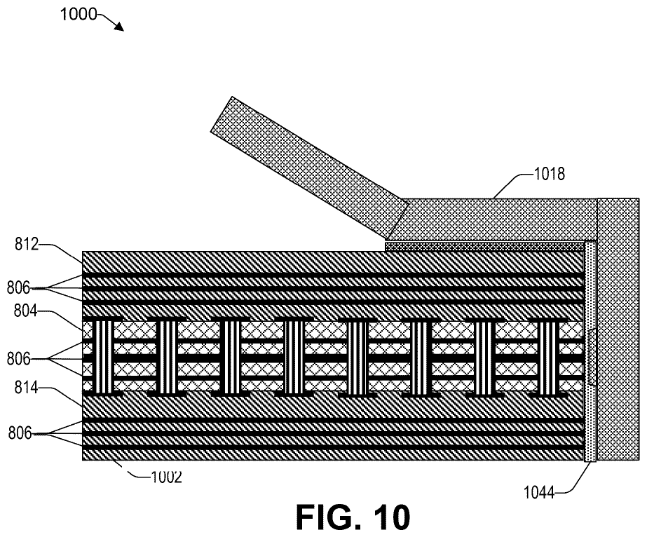

Reference is now made to FIG. 10, which depicts a magnified cross-sectional view of a heat spreader 1018 contacting a lateral surface of a PCB laminate 1002 with a core 1004 embedded with power and ground planes 1006, consistent with an illustrative embodiment. As shown, a plurality of (in other embodiments, one or more) power and ground planes 1006 are embedded within core 1004 and extend to thermal interface material 1044. The power and ground planes 1006 in core 1004 provide additional heat dissipation capability by absorbing and transferring heat in core 1006 to flanged edge 1040. Further as shown, one or more power and ground planes 1006 in core 1004 embody a thickness the same as the power and ground planes 1006 embedded in upper build-up layer 1012 and lower build-up layer 1014 while another of the power and ground planes 1006 in core 1004 embody a thickness that is greater than the power and ground planes 1006 embedded in upper build-up layer 1012 and lower build-up layer 1014. Power and ground planes 1006 embodying larger thicknesses provide additional heat dissipation out of core 1004. In embodiments, multiple power and ground planes 1006 in core 1004 embody a thickness greater than that of the power and ground planes 1006 embedded in upper build-up layer 1012 and lower build-up layer 1014. In further embodiments, all of the power and ground planes 1006 in core 1004 embody a thickness greater than that of the power and ground planes 1006 embedded in upper build-up layer 1012 and lower build-up layer 1014. In further embodiments, the power and ground planes 1006 in core 1004 are copper layers.

### Electronic Package Simulations

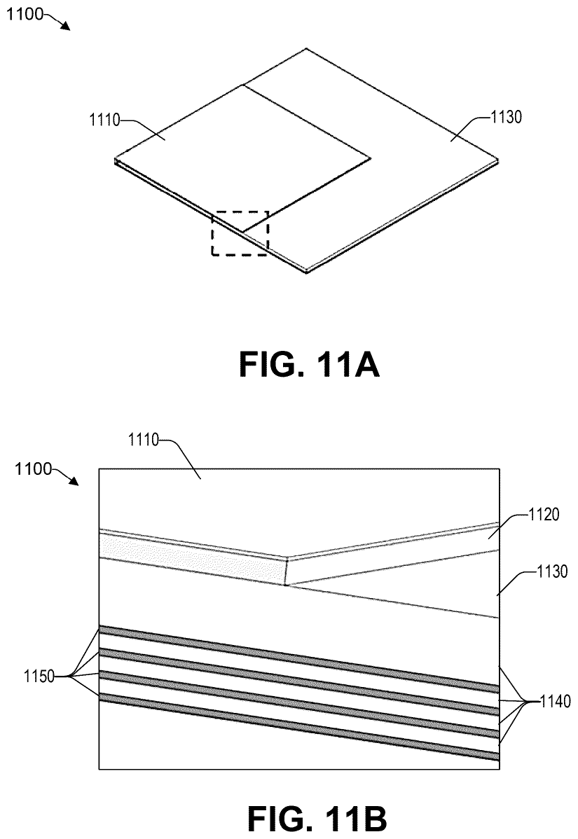

Reference is now made to FIG. 11A, which depicts an isometric view of an electronic package model 1100, consistent with an illustrative embodiment. Electronic package model 1100 is built to simulate an electronic package embodying a 6-2-6 substrate. As shown in FIGS. 11A and 11B, electronic package model 1100 includes a chip 1110, an interconnection layer 1120 (solder and underfill), and a PCB laminate 1130 having build-up layers 1140 alternating with power and ground planes 1150 (e.g., copper planes with dielectric and copper fill). It is noted that the electronic package model 1100 is a ¼ simulation model that is run by a software program. Accordingly, results take less time to calculate than running a full-scale model. Electronic package model 1100 further includes the following set parameters: a heat transfer coefficient of 2,000 W/m² (e.g., to account for a representation of a heat spreader on the electronic package model 1100), a maximum chip temperature of 85 degrees Celsius, an ambient chip temperature of 25 degrees Celsius, and a total power and ground plane 1150 thickness of 80 micrometers.

Furthermore, in this embodiment, chip 1110 embodies a thickness of 10 micrometers and a side length of 10 millimeters, interconnection layer 1120 embodies a thickness of 60 micrometers, a top build-up layer 1140 embodies a thickness of 165 micrometers, remaining build-up layers 1140 embody thicknesses of 35 micrometers each, a power and ground plane 1150 on a core embodies a thickness of 20 micrometers, and remaining power and ground planes 1150 embody a thickness of 20 micrometers each. In addition, a manageable heat density of 120 W/cm² is set (see FIG. 11).

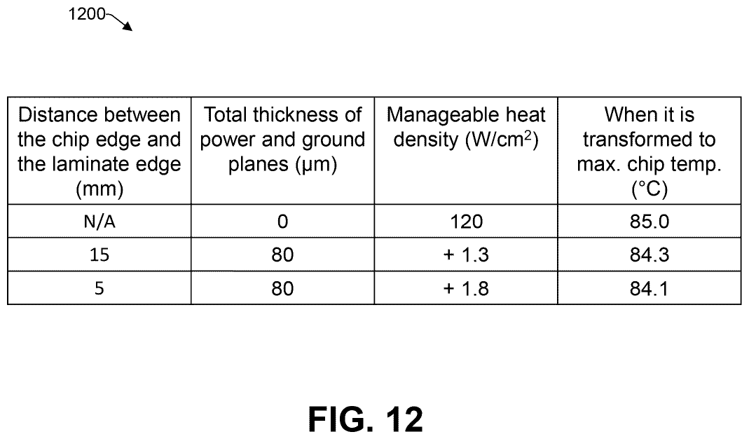

Reference is now made to FIG. 12, which presents a chart 1200 comparing distances between a chip 1110 edge and a PCB laminate 1130 edge and manageable heat density, consistent with an illustrative embodiment. As shown in chart 1200, when the total thickness of the power and ground planes is set (80 micrometers) and the distance between chip 1110 edge and PCB laminate 1130 edge is varied, manageable heat density is increased. When the distance between chip 1110 edge and PCB laminate 1130 edge is 15 millimeters, the manageable heat density increases to 121.3 W/cm² from 120 W/cm² (an increase of 1.3 W/cm²). When the distance between chip 1110 edge and PCB laminate 1130 edge is 5 millimeters, the manageable heat density increases to 121.8 W/cm² from 120 W/cm² (an increase of 1.8 W/cm²). Accordingly, it is observed that when the distance between chip 1110 edge and PCB laminate 1130 is reduced, a greater manageable heat density of the electronic package model 1100 is realized (1.8 W/cm² vs. 1.3 W/cm²). When the manageable heat densities are transformed to a maximum chip 1110 temperature, the maximum chip 1110 temperature of the 15-millimeter distance between edges is 84.3 degrees Celsius (a reduction of 0.7 degrees Celsius from the maximum chip 1110 temperature of 85 degrees Celsius) while the maximum chip 1110 temperature of the 5 millimeter distance between edges is 84.1 degrees Celsius (a reduction of 0.9 degrees Celsius from the maximum chip 1110 temperature of 85 degrees Celsius).

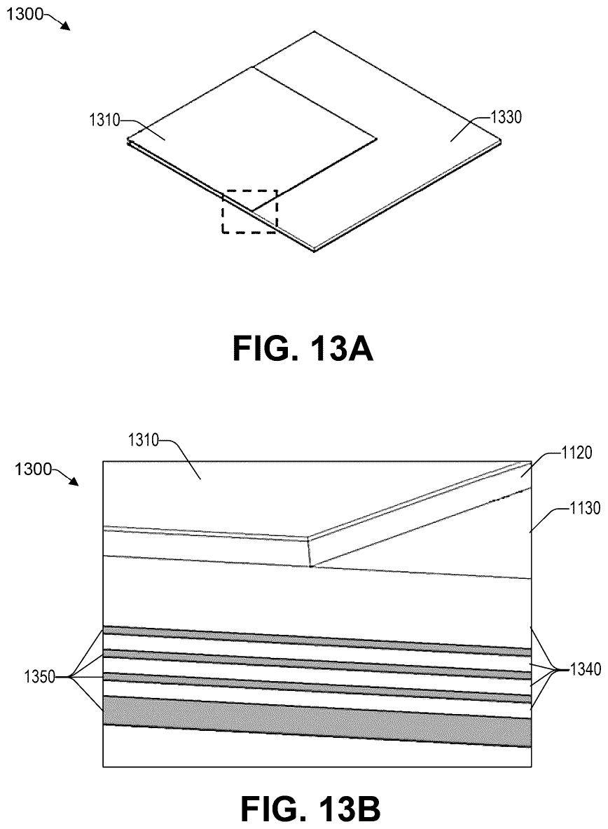

Reference is now made to FIG. 13A, which depicts an isometric view of an additional embodiment of an electronic package model 1300, consistent with an illustrative embodiment. Similar to electronic package model 1100, electronic package model 1300 is built to simulate an electronic package embodying a 6-2-6 substrate. As shown in FIGS. 13A and 13B, electronic package model 1300 includes a chip 1310, an interconnection layer 1320 (solder and underfill), and a PCB laminate 1330 having build-up layers 1340 alternating with power and ground planes 1350 (copper planes with dielectric and copper fill). It is noted that the electronic package model 1300 is also a ¼ simulation model that is run by a software program. Because electronic package model 1100 is a ¼ simulation model, results take less time to calculate than running a full-scale model. Electronic package model 1300 further includes the following set parameters: a heat transfer coefficient of 2,000 W/m² (to account for a representation of a heat spreader on the electronic package model 1300), a maximum chip temperature of 85 degrees Celsius, an ambient chip temperature of 25 degrees Celsius, and a distance between chip 1310 edge and PCB laminate 1330 edge of 15 millimeters and 5 millimeters (two set distance parameters).

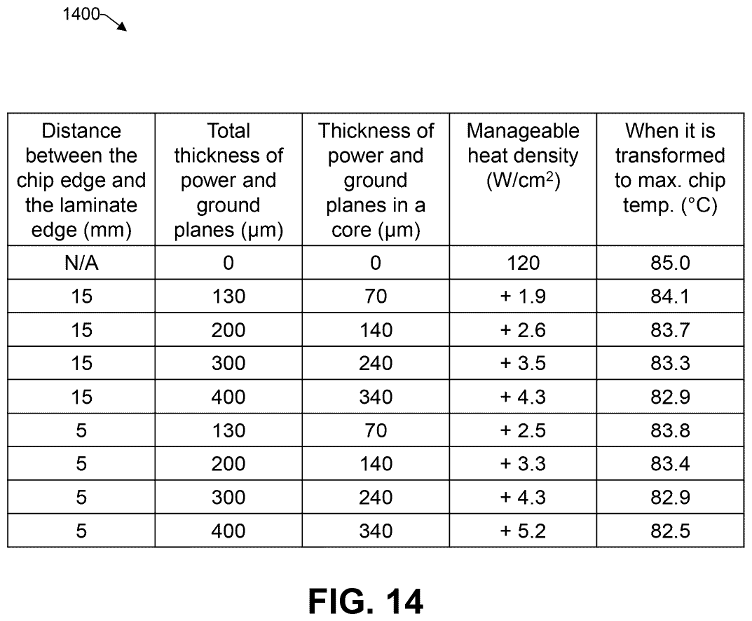

Furthermore, in this embodiment, chip 1310 embodies a thickness of 10 micrometers and a side length of 10 millimeters, interconnection layer 1320 embodies a thickness of 60 micrometers, a top build-up layer 1140 embodies a thickness of 165 micrometers, remaining build-up layers 1340 embody thicknesses of 35 micrometers each, a power and ground plane 1350 on a core embodies a variable thickness, and remaining power and ground planes 1350 embody a thickness of 20 micrometers each. In addition, a manageable heat density of 120 W/cm² is set (see FIG. 14).

Reference is now made to FIG. 14, which presents a chart 1400 comparing thicknesses of power and ground planes 1350 in a core and manageable heat density, consistent with an illustrative embodiment. As shown in chart 1400, when the distances between chip 1310 edge and PCB laminate 1330 edge is set (in groups of 15 millimeters and 5 millimeters, respectively) and the thickness of power and ground planes 1350 in a core is varied, manageable heat density is increased. When the distance between chip 1310 edge and PCB laminate 1330 edge is set at 15 millimeters and the thickness of power and ground planes 1350 is varied between 70 micrometers and 340 micrometers, the manageable heat density increases to 124.3 W/cm² from 120 W/cm² (increases of 1.9 W/cm², 0.7 W/cm², 0.9 W/cm², and 0.8 W/cm² respectively, for a total increase of 4.3 W/cm²). When the distance between chip 1310 edge and PCB laminate 1330 edge is set at 5 millimeters and the thickness of power and ground planes 1350 is varied between 70 micrometers and 340 micrometers, the manageable heat density increases to 125.2 W/cm² from 120 W/cm² (increases of 2.5 W/cm², 0.8 W/cm², 1.0 W/cm², and 0.9 W/cm² respectively, for a total increase of 5.2 W/cm²). So it is observed that when the thickness of power and ground planes 1350 in a core is increased, a greater manageable heat density of the electronic package model 1300 is realized (4.3 W/cm² vs. 1.9 W/cm² for thicknesses of 340 micrometers and 70 micrometers at a 15 millimeter edge distance and 5.2 W/cm² vs. 2.5 W/cm² for thicknesses of 340 micrometers and 70 micrometers at a 5 millimeter edge distance, respectively). When the manageable heat densities are transformed to a maximum chip 1310 temperature, the maximum chip 1310 temperature of the 15 millimeter distance between edges and at the greatest power and ground plane 1350 core thickness (340 micrometers) is 82.9 degrees Celsius (a reduction of 2.1 degrees Celsius from the maximum chip 1310 temperature of 85 degrees Celsius) while the maximum chip 1310 temperature of the 5 millimeter distance between edges and at the greatest power and ground plane core 1350 thickness (340 micrometers) is 82.5 degrees Celsius (a reduction of 2.5 degrees Celsius from the maximum chip 1110 temperature of 85 degrees Celsius).

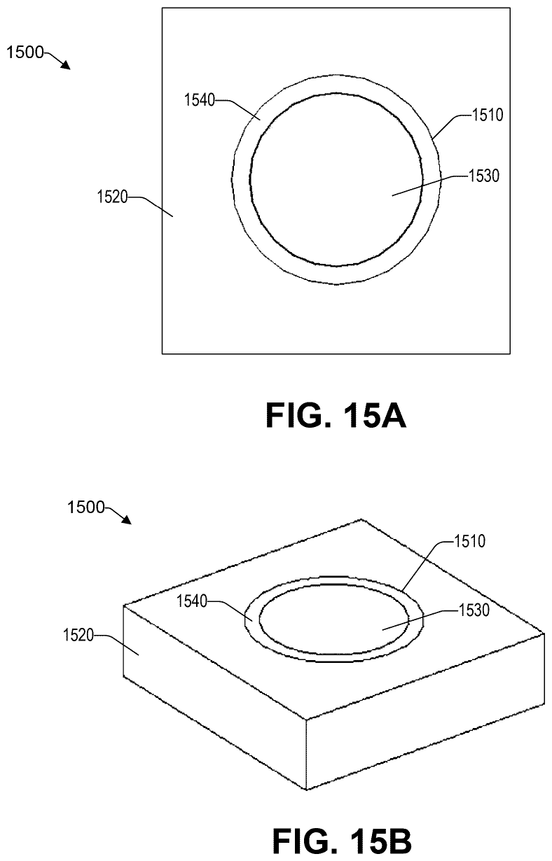

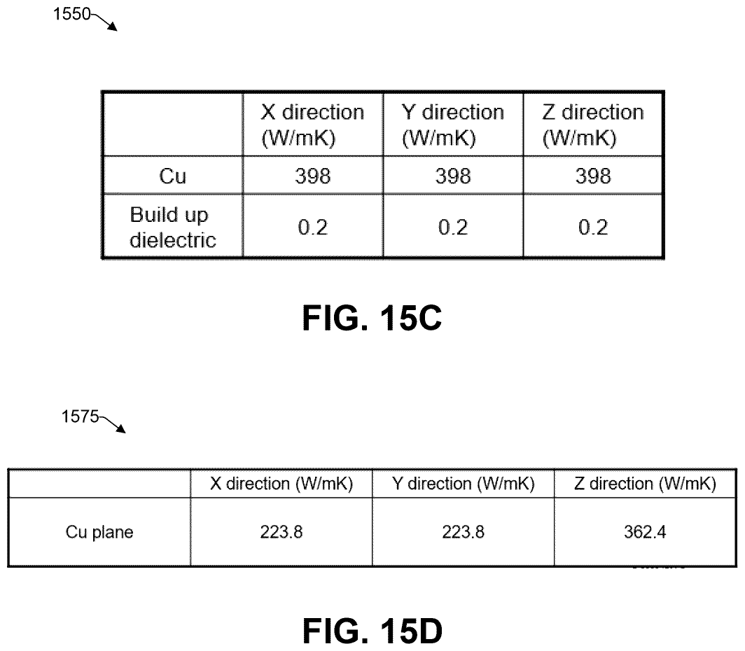

Reference is now made to FIG. 15A, which depicts a top view of a cross-sectional plane 1500 of a PCB laminate of an electronic package model embodying a filled via 1510, consistent with an illustrative embodiment. As shown, plane 1500 represents a cross-section of electronic package models 1100,1300 taken from PCB laminate 1130,1330 and is made of copper 1520. Plane 1500 includes side lengths of 150 micrometers and a depth from between 100 micrometers and 500 micrometers, as shown in FIG. 15B. Filled via 1510 includes a copper core 1530 and a build-up dielectric coating 1540 circumnavigating the copper core 1520. In embodiments, copper core 1530 embodies a diameter of 75 micrometers and build-up dielectric coating 1530 embodies a thickness of 7.5 micrometers.

Reference is now made to FIG. 15C, which presents a chart 1550 comparing thermal conductivities of materials in a cross-sectional plane 1510 of a PCB laminate 1130,1330 of an electronic package model 1100,1300 embodying a filled via 1510, consistent with an illustrative embodiment. As shown in chart 1550, copper material 1520 in plane 1500 embodies a thermal conductivity of 398 W/mK in the x, y, and z-directions while the build-up dielectric coating 1540 embodies a thermal conductivity of 0.2 W/mK in the x, y, and z-directions. When a simulation is run using either of electronic package models 1100,1300, the thermal conductivities displayed in FIG. 15C are used to derive thermal conductivities of entire regions of plane 1500, which are presented in FIG. 15D. As shown in chart 1575, plane 1500 embodies a thermal conductivity of 223.8 W/mK in the x and y-directions and a thermal conductivity of 362.4 W/mK in the z-direction. The increased thermal conductivity in the z-direction implies that additional heat dissipation is realized from chips 1110,1310 to the power and ground planes 1150,1350.

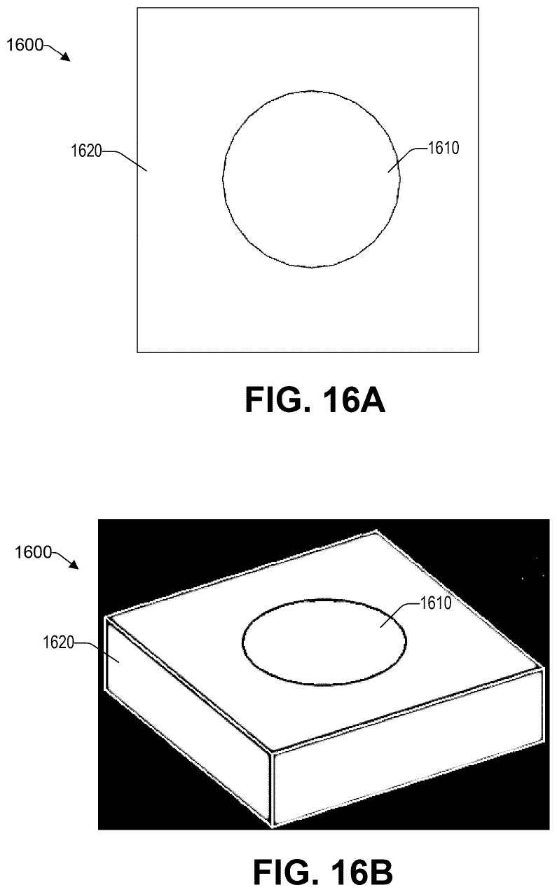

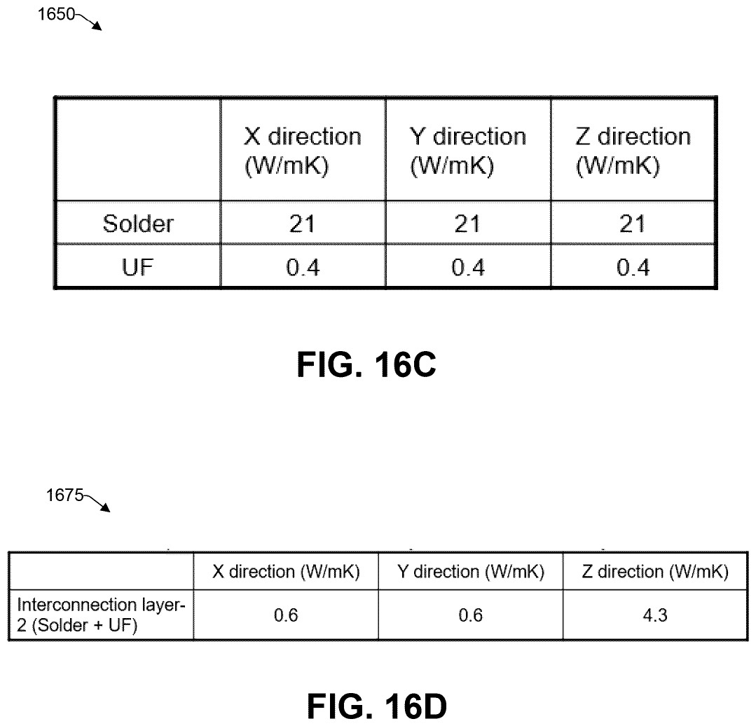

Reference is now made to FIG. 16A, which depicts a top view of a cross-sectional plane 1600 of an interconnection layer of an electronic package model, consistent with an illustrative embodiment. As shown, plane 1600 represents a cross-section of electronic package models 1100, 1300 taken from interconnection layer 1120,1320 and is made of underfill (UF) 1620. Plane 1600 includes side lengths of 150 micrometers and a depth of 20 micrometers, as shown in FIG. 16B. A solder section 1610 (as presented, a cross-section of a solder bump) is positioned in the core of plane 1600. In embodiments, solder section 1610 embodies a diameter of 75 micrometers.

Reference is now made to FIG. 16C, which presents a chart 1650 comparing thermal conductivities of materials in a cross-sectional plane 1610 of a PCB laminate 1130,1330 of an electronic package model 1100,1300 embodying a solder section 1610, consistent with an illustrative embodiment. As shown in chart 1650, underfill material 1620 in plane 1600 embodies a thermal conductivity of 0.4 W/mK in the x, y, and z-directions while the solder in solder section 1610 embodies a thermal conductivity of 21 W/mK in the x, y, and z-directions. When a simulation is run using either of electronic package models 1100,1300, the thermal conductivities displayed in FIG. 16C are used to derive thermal conductivities of entire regions of plane 1600, which are presented in FIG. 16D. As shown in chart 1675, plane 1600 embodies a thermal conductivity of 0.6 W/mK in the x and y-directions and a thermal conductivity of 4.3 W/mK in the z-direction. The thermal conductivities in chart 1675 are significantly lower than the thermal conductivities found in chart 1575 since the purpose of the interconnection layers 1120,1320 is to provide insulation.

For reference, the x and y-directions of planes 1500,1600 extend along a horizontal plane of electronic package models 1100,1300 while the z-direction of planes 1500,1600 extends along a vertical plane of electronic package models 1100,1300.

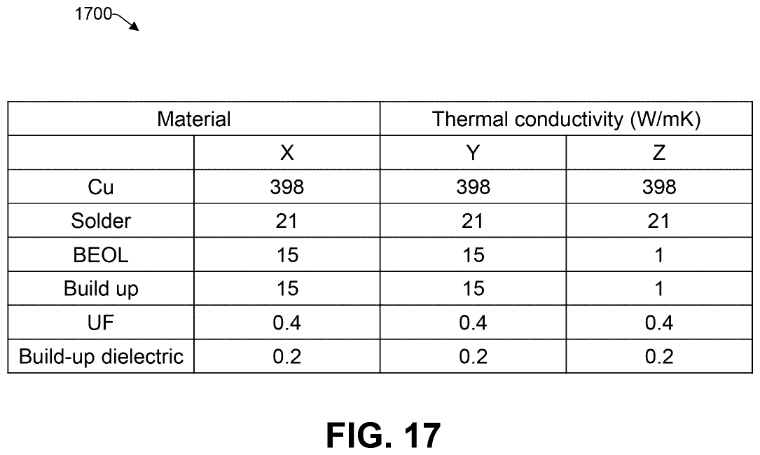

Reference is now made to FIG. 17, which presents a chart 1700 providing thermal conductivity characteristics of an electronic package model, consistent with an illustrative embodiment. As shown, chart 1700 provides thermal conductivities of materials utilized in electronic package models 1100,1300. In embodiments, copper (Cu) embodies a thermal conductivity of 398 W/mK in the x, y, and z-directions, solder embodies a thermal conductivity of 21 W/mK in the x, y, and z-directions, the back end of line (BEOL) embodies a thermal conductivity of 15 W/mK in the x and y-directions and a thermal conductivity of 1 in the z-direction, build-up layer material embodies a thermal conductivity of 15 W/mK in the x and y-directions and a thermal conductivity of 1 in the z-direction, underfill (UF) embodies a thermal conductivity of 0.4 W/mK in the x, y, and z directions, and build-up dielectric coating material embodies a thermal conductivity of 0.2 W/mK in the x, y, and z-directions.

### Additional Example Processes for Electronic Package Structures

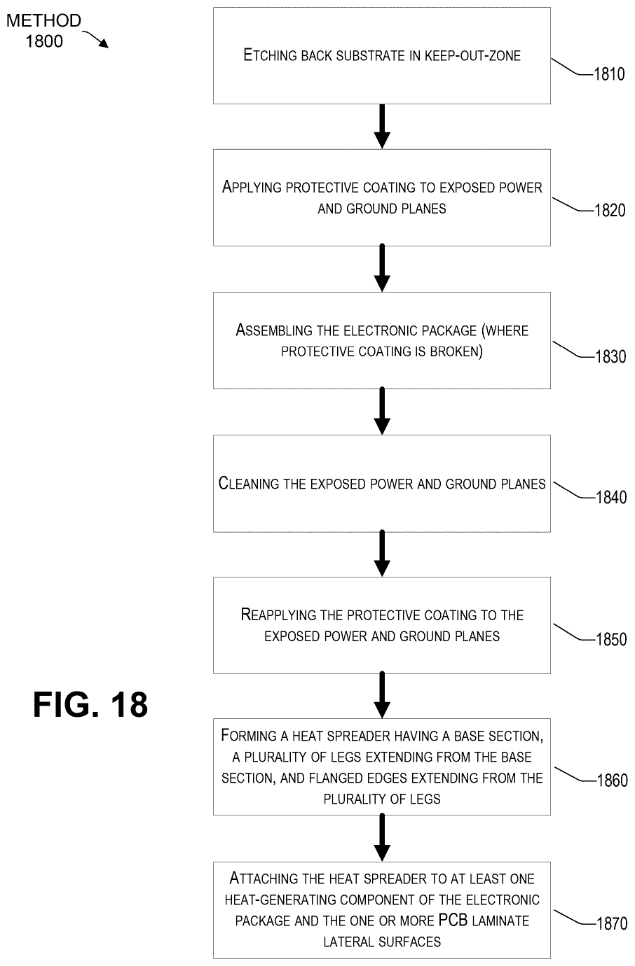

Reference is now made to FIG. 18, which is a simple flowchart for a method 1800 for manufacturing an electronic package, consistent with an illustrative embodiment. For discussion purposes, method 1800 is described with reference to the architecture of elements found in FIGS. 4-9. At block 1810, one or more lateral surfaces of a PCB laminate 402 are etched back, where the etching exposes power and ground planes 406 of the PCB laminate 402. At block 1820, a protective coating 542 is applied to the exposed power and ground planes 406. In an embodiment, the protective coating 542 is a corrosion-protective coating such as, but not limited to benzotriazole.

At block 1830, an electronic package 400 is assembled. During assembly of the electronic package 400, protective coating 542 is removed. At step 1840, the exposed power and ground planes 406 are cleaned. At step 1850, the protective coating 542 is reapplied to the exposed power and ground planes 406. At block 1860, a heat spreader 418 is formed having a base section 420, a plurality of legs 422 extending from the base section 420, and flanged edges 440 extending from each of the plurality of legs 422. At block 1870, the heat spreader 418 is attached to at least one heat-generating component 416 of the electronic package 400 and the one or more PCB laminate 402 lateral surfaces, where the flanged edges 440 of the heat spreader 418 are thermally connected to the one or more PCB laminate 402 lateral surfaces. During operation of the at least one heat-generating component 416, the flanged edges 440 dissipate heat from the one or more PCB laminate 402 lateral surfaces.

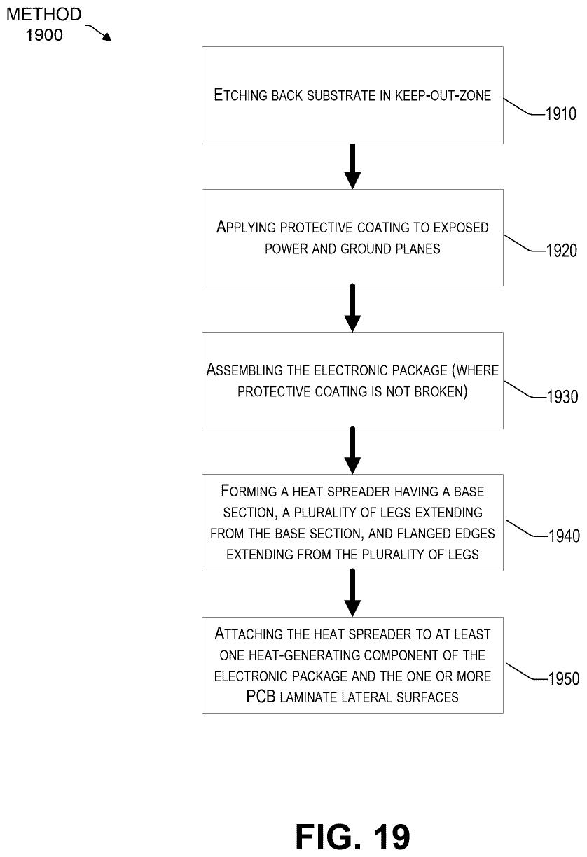

Reference is now made to FIG. 19, which is a simple flowchart for an additional method 1900 for manufacturing an electronic package, consistent with an illustrative embodiment. For discussion purposes, method 1900 is described with reference to the architecture of elements found in FIGS. 4-9. At block 1910, one or more lateral surfaces of a PCB laminate 402 are etched back, where the etching exposes power and ground planes 406 of the PCB laminate 402. At block 1920, a protective coating 542 is applied to the exposed power and ground planes 406. In an embodiment, the protective coating 542 is a corrosion-resistant metal.

At block 1930, an electronic package 400 is assembled. During assembly of the electronic package 400, protective coating 542 is not removed. At block 1940, a heat spreader 418 is formed having a base section 420, a plurality of legs 422 extending from the base section 420, and flanged edges 440 extending from each of the plurality of legs 422. At block 1950, the heat spreader 418 is attached to at least one heat-generating component 416 of the electronic package 400 and the one or more PCB laminate 402 lateral surfaces, where the flanged edges 440 of the heat spreader 418 are thermally connected to the one or more PCB laminate 402 lateral surfaces. During operation of the at least one heat-generating component 416, the flanged edges 440 dissipate heat from the one or more PCB laminate 402 lateral surfaces.

In an embodiment relative to either of methods 1800 and 1900, the etching 1810, 1910 is performed via at least one of laser dicing, reactive ion etching, chemical etching, and plasma etching.

In an embodiment relative to either of methods 1800 and 1900, one or both of methods 1800, 1900 further include positioning a thermal interface material 744 between the flanged edges 440 and the one or more PCB laminate 402 lateral surfaces.

In an embodiment relative to either of methods 1800 and 1900, one or both of methods 1800,1900 further include forming a protrusion 950 on one or more of the flanged edges 440, where the protrusion 950 extends into the thermal interface material 744 adjacent a core 404 of the PCB laminate 402.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

As used herein, the term “dielectric” is to be interpreted broadly and may include oxide materials such as SiO2, HfO2, ZrO2, HfSiO, HfZrO, and non-oxide materials such as SiN and AlN.

For the purposes of this disclosure, it is noted that any reference (including figures) to a single side or edge of either a heat spreader or a PCB laminate may also be applicable to one or more additional sides or edges (or all sides or edges) of the respective heat spreader or PCB laminate. For example, a protective coating 542 is applied to ends of power and ground planes 506 along one or more (or all) lateral surfaces of a PCB laminate 502.

With reference to the disclosed embodiments, the methods, apparatuses, and electronic packages utilize a modified heat spreader to achieve optimized cooling of electronic packages.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. An apparatus comprising:
a printed circuit board (PCB) laminate including a core and embedded power planes and ground planes positioned adjacent to the core;
one or more heat-generating components affixed to a top surface of the PCB laminate; and
a heat spreader attached in thermal contact with at least one of the one or more heat-generating components and one or more lateral surfaces of the PCB laminate;
wherein the heat spreader comprises flanged edges in thermal contact with the one or more lateral surfaces of the PCB laminate.

2. The apparatus of claim 1, further comprising a thermal interface material in thermal contact with and positioned between the flanged edges and the one or more PCB laminate lateral surfaces.

3. The apparatus of claim 2, further comprising a protrusion extending into the thermal interface material adjacent the core.

4. The apparatus of claim 2, wherein the thermal interface material is a dielectric material.

5. The apparatus of claim 1, wherein one or more of the embedded power planes and ground planes are exposed at the one or more PCB laminate lateral surfaces.

6. The apparatus of claim 5, wherein the one or more exposed embedded power planes and ground planes are coated with a protective coating.

7. The apparatus of claim 1, further comprising thermal vias extending from the top surface to the core of the PCB laminate.

8. The apparatus of claim 1, further comprising one or more copper layers embedded in the core and thermally connected to the flanged edges, wherein the one or more copper layers comprise a thickness greater than the embedded power planes and ground planes.

9. A heat spreader, comprising:
a base section;
a plurality of legs extending from the base section; and
flanged edges extending from each of the plurality of legs in a direction different than that of the base section and the plurality of legs;
wherein the flanged edges define a thermal contact surface configured to receive at least one printed circuit board (PCB) laminate lateral surface for heat dissipation of at least one heat-generating component.

10. The heat spreader of claim 9, further comprising a thermal interface material in thermal contact with the thermal contact surface.

11. The heat spreader of claim 10, wherein the thermal interface material is a dielectric material.

12. The heat spreader of claim 10, further comprising a protrusion extending into the thermal interface material, wherein the protrusion is configured to be positioned adjacent a core of a PCB laminate.

13. The heat spreader of claim 9, wherein each of the at least one PCB laminate lateral surface comprises one or more exposed power planes and ground planes thermally connected to the flanged edges.

14. A method for manufacturing an electronic package, comprising:
etching one or more lateral surfaces of a printed circuit board (PCB) laminate, wherein the etching exposes power and ground planes of the PCB laminate;
applying a protective coating to the exposed power and ground planes;
assembling the electronic package;
forming a heat spreader having a base section, a plurality of legs extending from the base section, and flanged edges extending from each of the plurality of legs; and
attaching the heat spreader to at least one heat-generating component of the electronic package and the one or more lateral surfaces of the PCB laminate, wherein the flanged edges of the heat spreader are thermally connected to the one or more lateral surfaces of the PCB laminate;
wherein during operation of the at least one heat-generating component, the flanged edges dissipate heat from the one or more lateral surfaces of the PCB laminate.

15. The method of claim 14, wherein the protective coating is a corrosion-resistant metal.

16. The method of claim 14, wherein the protective coating is a corrosion-protective coating, further wherein the protective coating is removed during the assembling.

17. The method of claim 16, further comprising:
cleaning the exposed power and ground planes of the PCB laminate; and
reapplying the protective coating to the exposed power and ground planes.

18. The method of claim 14, wherein the etching is performed via at least one of laser dicing, reactive ion etching, chemical etching, and plasma etching.

19. The method of claim 14, further comprising positioning a thermal interface material between the flanged edges and the one or more PCB laminate lateral surfaces.

20. The method of claim 19, further comprising forming a protrusion on one or more of the flanged edges, wherein the protrusion extends into the thermal interface material adjacent a core of the PCB laminate.
